(19) United States
(12) Patent Application Publication
(10) Pub. No.: US 2008/0302515 A1
(43) Pub. Date: Dec. 11, 2008

(54) FAN

(76) Inventors: Shih-Hua Ho, Taoyuan Hsien (TW); Hao-Ming Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 11/971,727

(22) Filed: Jan. 9, 2008

(30) Foreign Application Priority Data
Jun. 7, 2007 (TW) 096120523

(51) Int. Cl. H01L 23/473

(52) U.S. Cl. 165/120

(57) ABSTRACT

A fan includes an impeller, a motor and a frame. The impeller has a hub and a plurality of blades disposed around the hub. The motor connects to the impeller and drives it to rotate. The frame accommodates the impeller and the motor therein. The material of the impeller, the motor or the frame includes a color-changeable material.

### CROSS REFERENCE TO RELATED APPLICATIONS

This Non-provisional application claims priority under 35 U.S.C. §119(a) on Patent Application No. 096120523 filed in Taiwan, Republic of China on Jun. 7, 2007, the entire contents of which are hereby incorporated by reference.

### BACKGROUND OF THE INVENTION

1. Field of Invention

The invention relates to a fan and, in particular, to a fan with the function of instant status indication.

2. Related Art

As electronic products have better performance, higher operating frequencies, higher speeds and more compact sizes, they also produce more heat, which easily causes system instability and affects the reliability of the electronic products. Therefore, heat dissipation has become an important topic of the field.

The fan is a conventional heat dissipation device that utilizes airflow to force heat dissipation, thereby maintaining the electronic product at the regular operating temperature. Referring to FIG. 1, a conventional fan 1 consists of a frame 11, an impeller 12 disposed in the frame 11, and a status indicator 13 disposed on the frame 11. The status indicator 13 is electrically connected with the driving circuit board of the fan 1, and emits light to indicate various working statuses of the fan 1.

As the requirement for heat dissipation increases, the demand on the operating stability of the fan in the electronic product becomes higher. However, various environmental factors such as temperature, moisture and vibrations all have great effects on the fan operations. Therefore, it is useful to provide a status indicator, so that the user can know the operating status of the fan, thereby making sure that the electronic product operates stably. Nevertheless, there are even more problems with the indicator itself. If the status indicator malfunctions and the user cannot instantly realize, the fan may burn out. This may then result in damages to the electronic product, and the user may not realize the problem of the fan until the electronic product is damaged. In this case, the reliability and lifetime of the electronic product are not proper, and the cost is higher.

Therefore, it is an important subject to provide a fan that has the function of instant status indication and a versatile appearance.

### SUMMARY OF THE INVENTION

In view of the foregoing, an object of the invention is to provide a heat dissipation system and a fan that have the function of instant status indication and a colorful appearance.

To achieve the above, the invention discloses a fan including an impeller, a motor and a frame. The impeller includes a hub and a plurality of blades disposed around the hub. The motor is connected with the impeller for driving the impeller. The frame accommodates the impeller and the motor. The impeller, the frame or the motor includes a color-changeable material.

To achieve the above, the invention also discloses a heat dissipation system including a housing and a fan disposed in the housing. The fan includes an impeller, a motor and a frame. The impeller includes a hub and a plurality of blades disposed around the hub. The motor is connected with the impeller for driving the impeller. The frame accommodates the impeller and the motor. The impeller, the frame or the motor includes a color-changeable material.

As mentioned above, at least one of the impeller, frame and motor of the fan of the invention includes a color-changeable material. Using this feature, the impeller, frame or motor can directly detect the environmental factors or the working status of the fan and then show color changes. Therefore, the user can quickly obtain the color change to determine whether the fan operates abnormally and whether it should be replaced. This can elongate the lifetime of the electronic products. As a side effect, the fan of the invention has a colorful appearance as the color changes with environmental factors or its status.

### BRIEF DESCRIPTION OF THE DRAWINGS

The invention will become more filly understood from the detailed description and accompanying drawings, which are given for illustration only, and thus are not limitative of the present invention, and wherein:

FIG. 1 is a schematic view of a conventional fan; and

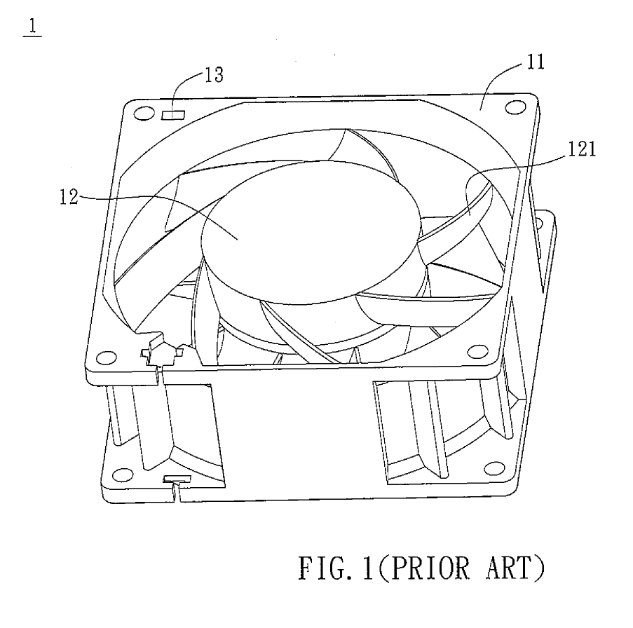

FIG. 2 is a cross sectional view of a fan according to an embodiment of the invention.

### DETAILED DESCRIPTION OF THE INVENTION

The present invention will be apparent from the following detailed description, which proceeds with reference to the accompanying drawings, wherein the same references relate to the same elements.

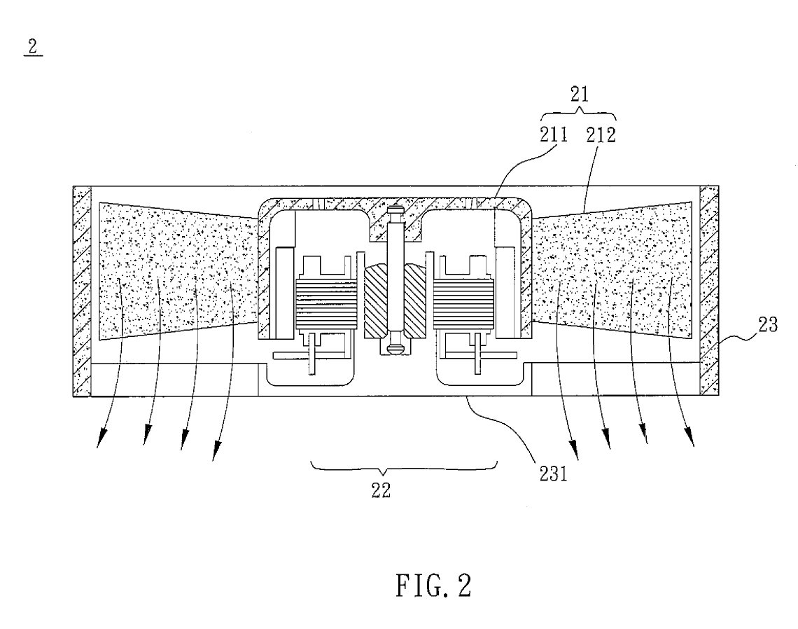

With reference to FIG. 2, a fan 2 according to an embodiment of the invention includes an impeller 21, a motor 22 and a frame 23. In this embodiment, the fan 2 is, for example but not limited to, an axial-flow fan. Of course, the fan 2 can be a centrifugal fan as well. The fan 2 can be disposed in an electronic product as the heat dissipation system of the electronic product.

The impeller 21 has a hub 211 and several blades 212 disposed around the hub 211. The motor 22 is used to drive the impeller 21 to rotate.

The frame 23 accommodates the impeller 21 and the motor 22. The frame 23 has a base 231, and the motor 22 is disposed on the base 231.

The impeller 21, the frame 23 or the motor 22 has a color-changeable material. The color-changeable material can be formed only on a local part of the impeller 21, the frame 23 or the motor 22. It can also be formed all over the impeller 21, the frame 23 or the motor 22. In the embodiment, the color-changeable material can be disposed on the surfaces of the impeller 21, the frame 23 and/or the motor 22 by doping, coating or adhering. Alternatively, the color-changeable material can be mixed with the plastic material, and then integrally form the impeller 21, the frame 23 or the motor 22. Herein, the impeller 21, the frame 23 or the motor 22 can be integrally formed as a single unit by injection molding.

The color-changeable material can change its color according to the environmental factors. Therefore, it can quickly reflect the operating temperature, accumulated operating time, or vibrations of the fan 2. Moreover, it produces an enjoyable visual effect. The environmental factors mentioned herein include temperature, moisture, airflow direction, light or vibrations.

In this embodiment, the color-changeable material changes its color according to the temperature. For example, when the temperature varies from low temperature to high temperature, the color of the color-changeable material changes from blue to purple, and then from purple to red. This is merely an example, and should not be used to restrict the invention.

FIG. 2 shows the example that the color-changeable material is distributed all over the impeller 21. Since the temperatures of different parts of the impeller 21 are different during the operation of the impeller 21, the color continuously varies from the central axis to the edge and from the air inlet to the air outlet. Thus, the fan 2 in operation can represent a colorful feature.

Moreover, the fan 2 can be disposed with one or more light sources for illuminating the impeller 21, the frame 23 and/or the motor 22. These light sources enable the fan 2 to present different colors of the color-changeable material even in a dark environment. The light sources can be disposed inside or outside the frame 23. In this case, the light source can be a light bulb, a light-emitting diode (LED), or an organic light-emitting diode (OLED).

Furthermore, the hub 211 can be formed with several heat dissipation holes to help decreasing the temperature of the motor during the operation of the fan 2.

In summary, at least one of the impeller, frame and motor of the fan of the invention includes a color-changeable material. Using this feature, the impeller, frame or motor can directly detect the environmental factors or the working status of the fan and then show color changes. Therefore, the user can quickly obtain the color change to determine whether the fan operates abnormally and whether it should be replaced. This can elongate the lifetime of the electronic products. As a side effect, the fan of the invention has a colorful appearance as the color changes with environmental factors or its status.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A fan comprising:
an impeller;
a motor coupled with the impeller for driving the impeller; and
a frame accommodating the impeller and the motor, wherein the impeller, the frame or the motor comprises a color-changeable material.

2. The fan of claim 1, wherein the color-changeable material is formed on a local part of the impeller, the frame or the motor.

3. The fan of claim 1, wherein the color-changeable material is distributed all over the impeller, the frame or the motor.

4. The fan of claim 1, wherein the color-changeable material is formed on a surface of the impeller, the frame and/or the motor by doping, coating, or adhering.

5. The fan of claim 1, wherein a color of the color-changeable material changes along with a variation of temperature, moisture, airflow direction, light or vibration.

6. The fan of claim 1, further comprising at least one light source illuminating the impeller, the frame or the motor.

7. The fan of claim 6, wherein the light source is a light bulb, a light-emitting diode (LED) or an organic light-emitting diode (OLED).

8. The fan of claim 6, wherein the light source is disposed inside the frame.

9. The fan of claim 6, wherein the light source is disposed outside the frame.

10. The fan of claim 1, wherein the impeller has a hub and a plurality of blades disposed around the hub.

11. The fan of claim 10, further comprising a plurality of heat dissipation holes disposed on the hub.

12. The fan of claim 1, being applied to a heat dissipation system of an electronic product.

13. The fan of claim 1, wherein the color-changeable material is mixed with a plastic material so as to integrally form the impeller, the frame or the motor.

14. The fan of claim 1, wherein when the temperature increases, a color of the color-changeable material changes from blue to purple, and then from purple to red.
